(19) United States
(12) Patent Application Publication
(10) Pub. No.: US 2025/0372363 A1
(43) Pub. Date: Dec. 4, 2025

(54) METHOD AND APPARATUS FOR HARD MASK DEPOSITION

(71) Applicant: ASM IP Holding B.V., Almere (NL)

(72) Inventors: Vincent Vandalon, Heverlee (BE); Marko Tuominen, Helsinki (FI); Yoann Tomczak, Leuven (BE); Nadadur Veeraraghavan Srinath, Chandler, AZ (US); YongGyu Han, Leuven (BE); Kranthi Kumar Vaidyula, Chandler, AZ (US); David Zanders, Leuven (BE)

(21) Appl. No.: 19/221,890

(22) Filed: May 29, 2025

Related U.S. Application Data
(60) Provisional application No. 63/654,636, filed on May 31, 2024.

(51) Int. Cl. H01L 21/02; C23C 16/04; C23C 16/40; C23C 16/455

(52) U.S. Cl. CPC H01L 21/02192; C23C 16/042; C23C 16/405; C23C 16/45525; H01L 21/02118

(57) ABSTRACT

Methods of depositing an organic polymer in a gap on a substrate, methods of depositing a hard mask on a patterned substrate, structures and semiconductor devices formed using the methods, and deposition assemblies for performing the methods are provided. In a method, a substrate having a top surface and a gap is provided in a reaction chamber. The gap has an inner surface including a first material and the top surface includes a second material. The method further includes forming a first blocking on the top surface, and selectively depositing an organic polymer from a vapor phase on the inner surface relative to the first blocking. After depositing a predetermined amount of the organic polymer, a second blocking is formed on the top surface and an organic polymer is selectively deposited from a vapor phase on the inner surface relative to the second blocking.

### CROSS-REFERENCE TO RELATED APPLICATION(S)

This application claims the benefit of U.S. Provisional Application 63/654,636 filed on May 31, 2024, the entire contents of which are incorporated herein by reference.

### FIELD

The present disclosure relates to methods for the manufacture of semiconductor devices, such as creating gate cut in a replacement metal gate feature. More particularly, the disclosure relates to methods for depositing a hard mask and selectively etching materials on a substrate.

### BACKGROUND

Semiconductor device fabrication processes generally use advanced methods for creating fine patterns of features on a substrate by patterning the surface of the substrate and removing material from the substrate using, for example, wet etch and/or dry etch processes. As a density of devices on a substrate increases, it becomes increasingly desirable to form features with smaller dimensions.

To regulate the areas from which material is removed, photoresists and hard masks may be used. However, the manufacture of advanced features, such as deep trenches with small critical dimensions, poses challenges for the current hard mask materials to avoid etching of the feature edges during prolonged and/or aggressive etching processes, and losing critical dimension control. Thus, new hard mask materials, as well as new methods to deposit them are sought in the art. Further, alternative methods of achieving etch selectivity are desired, to allow the use of various material combinations in semiconductor devices.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of depositing an organic polymer in a gap on a substrate, to methods of depositing a hard mask on a patterned substrate, structures and semiconductor devices formed using the methods, and to deposition assemblies for performing the methods described herein.

Without limiting the generality of the disclosure, the current methods may be of particular use in forming of gate cuts in replacement metal gate structure. Such methods require long etching time and accurate control of the critical dimension at the top of the gap being etched. To form such a structure, the non-etchable areas of the pattern need to be protected by a durable hard mask, such that the critical dimension of the gap is not compromised while a sufficiently deep gap (or hole) can be formed.

In the present disclosure, a two-phase etching process is disclosed. First, an initial mask is formed, and it is used to form a gap in the substrate. This gap, however, is formed to guide the deposition of a hard mask on the initial mask. The hard mask is formed of a material, such as a metal oxide, metal nitride or a semimetal nitride, for example aluminum oxide, yttrium oxide, titanium nitride or silicon nitride, that is able to withstand a long enough etch process to form the final gate cut. The methods utilize a contrast between the initial mask material and the material underlying the initial mask. This contrast enables the selective deposition of an organic polymer in the gap, which in turn allows selective deposition of the further hard mask on the initial mask. This creates the desired etch contrast for forming the gate cut through the organic polymer into the gap.

Thus, in one aspect, a method of selectively depositing an organic polymer in a gap is disclosed. In the method, a substrate having a top surface and a gap therein is provided in a reaction chamber. The gap has an inner surface comprising a first material and the top surface comprises a second material. The method further comprises forming a first blocking on the top surface, and selectively depositing an organic polymer from a vapor phase on the inner surface relative to the first blocking. After depositing a predetermined amount of the organic polymer, a second blocking is formed on the top surface and an organic polymer is selectively deposited from a vapor phase on the inner surface relative to the second blocking.

In some embodiments, forming the second blocking on the top surface comprises exposing the substrate to a gas mixture comprising oxygen. In some embodiments, forming the second blocking on the top surface comprises exposing the substrate to a gas mixture comprising water vapor. In some embodiments, forming the second blocking on the top surface comprises exposing the substrate to a gas mixture comprising oxygen and water vapor. In some embodiments, forming the second blocking is performed at a temperature of below 100° C. In some embodiments, forming the second blocking comprises removing the first blocking. In some embodiments, the first blocking is removed by a plasma treatment. In some embodiments, forming the second blocking comprises restoring the top surface properties for blocking. In some embodiments, forming the second blocking comprises exposing the substrate to ambient environment.

In some embodiments, the second material comprises silicon. In some embodiments, the second material is selected from a group consisting of SiO₂, SiN, SiC, SiOC, SiON, SiOCN, Si and combinations thereof.

In some embodiments, the first material is an electrically conductive material. In some embodiments, the first material is selected from a group consisting of a SiGe, metal, amorphous carbon, metal oxide and metal nitride. In some embodiments, the first material is a transition metal. In some embodiments, the first material is a metal selected from a group consisting of Ti, Zr, Hf, V, Nb, Ta, Cr, Mo, W, Mn, Fe, Ru, Co, Ni, Cu, Zn and Al. In some embodiments, the first material comprises elemental metal. In embodiments, in which the first material comprises SiGe, the portion of Ge needs to be sufficiently high for achieving the deposition according to the current disclosure. The proportion of Ge in the SiGe material may be higher than about 10 at-%, such as at least about 15 at-%, or at least about 35%, or at least about 50 at-%, such as about 40 at-% or about 60 at-%.

In some embodiments, the first blocking and the second blocking comprise silylating the top surface. In some embodiments, the forming of second blocking is repeated.

In some embodiments, the organic polymer comprises polyimide. In some embodiments, the organic polymer consists substantially of polyimide. In some embodiments, the organic polymer is deposited by a cyclic deposition process. In some embodiments, the organic polymer is deposited to substantially fill the gap.

In another aspect, a method of selectively depositing a metal-containing layer on a top surface of a substrate is disclosed. The method comprises providing the substrate having a top surface and a gap therein in a reaction chamber, wherein the gap has an inner surface comprising a first material and the top surface comprises a second material. The method further comprises forming a first blocking on the top surface and selectively depositing an organic polymer from a vapor phase on the inner surface relative to the first blocking. After depositing a predetermined amount of the organic polymer, a second blocking is formed on the top surface, an organic polymer is selectively deposited from a vapor phase on the inner surface relative to the second blocking and the metal-containing layer is selectively deposited on the top surface relative to the organic polymer.

In some embodiments, the metal-containing layer is a metal oxide layer or a metal nitride layer. In some embodiments, the metal-containing layer is a titanium nitride layer. In some embodiments, metal-containing layer is an aluminum oxide layer or an yttrium oxide layer. In some embodiments, the metal containing layer is an etch-stop layer. In some embodiments, the etch-stop layer consists substantially of yttrium oxide. In some embodiments, the metal-containing layer comprises a high k material. Transition metal oxides and transition metal nitrides are the most used materials for the metal-containing materials for the purposes of the current disclosure. However, in some embodiments, silicon nitride may be useful. In particular, transition metal oxides and nitrides may enable the etching of narrow holes or gaps having a depth of more than 150 nm or even more than 200 nm. Such etching depths are needed in, for example, when forming a gate cut in a gate cut last scheme for producing logic devices.

In yet another aspect, a deposition assembly for depositing an etch-stop layer is disclosed. The deposition assembly is configured and arranged to perform a method according to the current disclosure. In particular, the deposition assembly comprises a reaction chamber configured and arranged to hold the substrate comprising a surface and a gap therein. The deposition assembly further comprises a first blocking reactant vessel, and in embodiments in which the first blocking and the second blocking are different, a second blocking reactant vessel. The deposition assembly also comprises a first organic polymer precursor vessel and a second precursor vessel for selectively depositing an organic polymer as described herein on an inner surface of the gap. The deposition assembly comprises a metal precursor vessel and a second precursor vessel for depositing the metal-containing material.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIG. 1 is a block diagram of exemplary embodiments of a method according to the current disclosure.

FIGS. 2a-2h are schematic presentations of a method according to the current disclosure.

### DETAILED DESCRIPTION

The description of exemplary embodiments of methods, structures, devices and deposition assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other. The headings provided herein, if any, are for convenience only and do not necessarily affect the scope or meaning of the claimed invention.

The present disclosure generally relates to methods of selectively depositing an organic polymer on a substrate, to methods of selectively depositing a metal-containing layer, such as an etch-stop layer, on a substrate, to methods of etching a structure, and to structures and semiconductor devices formed using methods described herein, as well as to deposition assemblies for performing the methods.

Exemplary methods of the current disclosure can be used to deposit an etch-stop layer on a patterned hard mask. Hard mask is generally used to guide etching of material to intended regions of layers on a semiconductor substrate. However, current hard mask materials may have drawbacks, as their etch resistance may not be sufficient for all applications. For example, shrinking dimensions of semiconductor devices pose challenges to the current hard mask materials in forming a gate cut into a partially fabricated device, as the edges of the hard mask surrounding the area to be etched may become etched and thus lead to inaccurate pattern transfer.

In the current disclosure, the substrate is patterned. Thus, at least one layer on the substrate comprises a gap. Material to be etched during manufacturing the desired device is positioned under the hard mask, and the etching will be performed on areas of the underlying material that are exposed to etching treatment through the gaps. Etching transfers the pattern downwards to the one or more layers beneath the patterned layer-which may itself comprise one or multiple layers. In embodiments, in which the etching process creates a gate cut, the original patterned layer may not be sufficiently etch resistant to allow extended etching without changes in the critical dimensions (i.e. width) of the gap.

The gap thus defines the areas to be etched, and the accuracy of the pattern transfer by etching is dependent on the etching resistivity of the gap edge.

The etch-stop layer according to the current disclosure may have higher etch resistivity than the underlying patterned layer (which may be a hard mask). Also in embodiments, in which the etch resistance of the etch-stop layer is not significantly higher than that of the underlying patterned layer, it may protect the underlying material so that its material is degraded less than it would be in the absence of the etch-stop layer. In some embodiments, the etch-stop layer has higher etch resistivity than the organic polymer. Thus, the organic polymer may be etched away without damaging the etch-stop layer. In some embodiments, the etch-stop layer is damaged, but the etch-stop layer reduces the damage to the underlying patterned layer such that the critical dimension of the gap is not substantially altered during the etch process. By selective etching is herein meant that the target material to be etched exhibits an etch rate of greater than 20 times, greater than 10 times, or greater than 5 times the etch rate of the metal-containing layer.

In accordance with further embodiments of the disclosure, a structure is provided. The structure can be formed according to a method as set forth herein. In accordance with further examples of the disclosure, a device comprises or is formed using a structure as described herein.

In this disclosure, “gas” can include material that is a gas at normal temperature and pressure (NTP), a vaporized solid and/or a vaporized liquid, and can be constituted by a single gas or a mixture of gases, depending on the context. A first organic polymer precursor may be provided to the reaction chamber in gas phase. A second organic polymer precursor may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

By “blocking” is herein meant a layer or a chemical treatment of a surface, such as a top surface of a patterned substrate, that prevents, or substantially reduces, the vapor deposition of a material on a substrate surface. Blocking may be selective, such that only certain types of surfaces are blocked from deposition, while on other surfaces, the deposition-blocking effect is not present, or is present to a significantly lower degree. In other words, there may be a contrast between blocking of different surfaces.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. However, a reactant may also contribute to the resulting compound or element in certain embodiments.

As used herein, “first organic polymer precursor” and “second organic polymer precursor” include a gas or a material that can become gaseous and that can be used to deposit an organic polymer. In some embodiments, organic polymer is deposited using a cyclic deposition process, in which two precursors (i.e. first organic polymer precursor and a second organic polymer precursor) are used. In such embodiments, the method comprises providing a first organic polymer precursor and a second organic polymer precursor into the reaction chamber in vapor phase. Thus, an organic polymer may be deposited using a molecular layer deposition (MLD).

As used herein, “metal precursor” includes a gas or a material that can become gaseous and that can be represented by a chemical formula that includes a metal. In embodiments, a metal-containing layer is deposited using a cyclic deposition process, in which two precursors are used. In such embodiments, the method comprises providing a metal precursor and a second precursor into the reaction chamber in vapor phase. The second precursor may be, for example, an oxygen precursor, in cases where the metal-containing layer comprises a metal oxide. In embodiments, in which the metal-containing layer comprises a metal nitride, the second precursor is a nitrogen precursor.

In some embodiments, a precursor is provided in a mixture of two or more compounds. In a mixture, the other compounds in addition to the precursor may be inert compounds or elements. In some embodiments, a precursor is provided in a composition. Composition may be a liquid or a gas in standard conditions.

In this disclosure, performing two processing phases continuously can refer to one or more of the following: without breaking a vacuum, without interruption as a timeline, without any material intervening step, without changing treatment conditions, immediately thereafter or as a next step.

As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous.

In the current disclosure, a deposition process may comprise a cyclic deposition process, such as an atomic layer deposition (ALD) process or a cyclic chemical vapor deposition (VCD) process. The term “cyclic deposition process” can refer to the sequential introduction of precursor(s) and/or reactant(s) into a reaction chamber to deposit material, such as passivation material or hard mask material, on a substrate. Cyclic deposition includes processing techniques such as atomic layer deposition (ALD), cyclic chemical vapor deposition (cyclic CVD), and hybrid cyclic deposition processes that include an ALD component and a cyclic CVD component. The process may comprise a purge step between providing precursors or between providing a precursor and a reactant in the reaction chamber.

The process may comprise one or more cyclic phases. For example, pulsing of two precursors may be repeated. In some embodiments, the process comprises or one or more acyclic phases. In some embodiments, the deposition process comprises the continuous flow of at least one precursor. In some embodiments, a precursor may be continuously provided in the reaction chamber. In such an embodiment, the process comprises a continuous flow of a precursor or a reactant. In some embodiments, one or more of the precursors and/or reactants are provided in the reaction chamber continuously.

Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a first precursor into the reaction chamber. In some embodiments, the cyclic deposition process comprises purging the reaction chamber after providing a second precursor into the reaction chamber. In some embodiments, the cyclic deposition process comprises purging the reaction chamber after providing a first precursor into the reaction chamber, and after providing second precursor into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, whereas in MLD, the precursors may be fully organic molecules.

CVD-type processes typically involve gas phase reactions between two or more precursors and/or reactants. The precursor(s) and reactant(s) can be provided simultaneously to the reaction space or substrate, or in partially or completely separated pulses. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

As used herein, the term “purge” refers to a procedure in which vapor phase precursors and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be performed between two pulses of gases which react with each other. However, purging may be performed between two pulses of gases that do not react with each other. For example, a purge, or purging may be provided between pulses of two precursors or between a precursor and a reactant. Purging may avoid or at least reduce gas-phase interactions between the two gases reacting with each other. It shall be understood that a purge can be performed either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain or another means of separating the two spaces, to a second location to which a second precursor is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

The process may comprise one or more cyclic phases. In some embodiments, the process comprises or one or more acyclic (i.e. continuous) phases. In some embodiments, the deposition process comprises the continuous flow of at least one precursor. In such an embodiment, the process comprises a continuous flow of a first polymer precursor or second polymer precursor. In some embodiments, one or more of the precursors are provided in the reaction chamber continuously.

In some embodiments, the cyclic deposition process according to the current disclosure comprises a thermal deposition process. In thermal deposition, the chemical reactions are promoted by increased temperature relevant to ambient temperature. Generally, temperature increase provides the energy needed for the formation of the target material in the absence of other external energy sources, such as plasma, radicals, or other forms of radiation. In some embodiments, the method according to the current disclosure comprises a plasma-enhanced deposition method, for example PEALD or PECVD. For example, in some embodiments, the hard mask deposition may be performed by PEALD or PECVD.

As used herein, silicon oxide refers to a material that includes silicon and oxygen. Silicon oxide can be represented by the formula SiOx, where x can be between 0 and 2 (e.g., SiO₂). In some cases, the silicon oxide may not include stoichiometric silicon oxide. In some cases, the silicon oxide can include other elements, such as carbon, nitrogen, hydrogen, or the like.

Silicon carbide (SiC) can refer to a material that includes silicon and carbon. Silicon carbide need not necessarily be a stoichiometric composition. An amount of silicon can range from 5 to 50 at %; an amount of carbon can range from about 50 to about 95 at %. In some embodiments, SiC films may comprise one or more elements in addition to Si and C, such as H or N.

Silicon oxycarbide (SiOC) can refer to material that comprises silicon, oxygen, and carbon. As used herein, unless stated otherwise, SiOC is not intended to limit, restrict, or define the bonding or chemical state, for example, the oxidation state of any of Si, O, C, and/or any other element in the film. In some embodiments, SiOC thin films may comprise one or more elements in addition to Si, O, and C, such as H or N. In some embodiments, the SiOC films may comprise Si—C bonds and/or Si—O bonds. In some embodiments, the SiOC films may comprise Si—C bonds and Si—O bonds and may not comprise Si—N bonds. In some embodiments, the SiOC films may comprise Si—H bonds in addition to Si—C and/or Si—O bonds. In some embodiments, the SiOC films may comprise more Si—O bonds than Si—C bonds, for example, a ratio of Si—O bonds to Si—C bonds may be from about 1:10 to about 10:1. In some embodiments, the SiOC films may comprise from about 0% to about 50% carbon on an atomic basis. In some embodiments, the SiOC films may comprise from about 0.1% to about 40%, from about 0.5% to about 30%, from about 1% to about 30%, or from about 5% to about 20% carbon on an atomic basis. In some embodiments, the SiOC films may comprise from about 0% to about 70% oxygen on an atomic basis. In some embodiments, the SiOC films may comprise from about 10% to about 70%, from about 15% to about 50%, or from about 20% to about 40% oxygen on an atomic basis. In some embodiments, the SiOC films may comprise about 0% to about 50% silicon on an atomic basis. In some embodiments, the SiOC films may comprise from about 10% to about 50%, from about 15% to about 40%, or from about 20% to about 35% silicon on an atomic basis. In some embodiments, the SiOC films may comprise from about 0.1% to about 40%, from about 0.5% to about 30%, from about 1% to about 30%, or from about 5% to about 20% hydrogen on an atomic basis. In some embodiments, the SiOC films may not comprise nitrogen. In some other embodiments, the SiOC films may comprise from about 0% to about 40% nitrogen on an atomic basis (at %). By way of particular examples, SiOC films can be or include a layer comprising SiOCN. In some embodiments, silicon oxycarbide can be represented by the chemical formula Si₂OₓC_{y}, where z can range from about 0 to about 2, x can range from about 0 to about 2, and y can range from about 0 to about 5.

Silicon oxycarbonitride refers to material that comprises silicon, oxygen, nitrogen and carbon. As used herein, unless stated otherwise, SiOCN is not intended to limit, restrict, or define the bonding or chemical state, for example, the oxidation state of any of Si, O, C, N and/or any other element in the film. In some embodiments, SiOCN is material that can be represented by the chemical formula Si_{z}OₓC_{y}N_{w}, where z can range from about 0 to about 2, x can range from about 0 to about 2, y can range from about 0 to about 2, and w can range from about 0 to about 2.

The term metal oxide can refer to a material that includes a metal and oxygen. The metal or metalloid can be, for example, one or more of aluminum, hafnium, zirconium, indium and yttrium. The term metal nitride can refer to a material that includes a metal and nitrogen. The metal can be, for example, one or more of aluminum, hafnium, zirconium, indium and yttrium.

Selective deposition according to the current disclosure can be given as a percentage calculated by [(deposition on first material)−(deposition on second material)]/(deposition on the first material). Deposition can be measured in a variety of ways. In some embodiments, deposition may be given as the measured thickness of the deposited material. In some embodiments, deposition may be given as the measured amount of material deposited. Thus, the passivation material grows preferentially on the first material, while it is deposited to a lesser extent, or not at all, on the second material. In some embodiments, deposition of the passivation material on the first material relative to the second material is at least about 90% selective, which may be selective enough for some particular applications. In some embodiments, deposition of the passivation material on the first material relative to the second material is at least about 80% selective, which may be selective enough for some particular applications. In some embodiments the deposition on the first material relative to the second material is at least about 50% selective, which may be selective enough for some particular applications.

### Drawings

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements, such as thicknesses of material layers, in the figures may be exaggerated relative to other elements to help improve the understanding of illustrated embodiments of the present disclosure. The structures and devices depicted in the drawings may contain additional elements and details, which may be omitted for clarity.

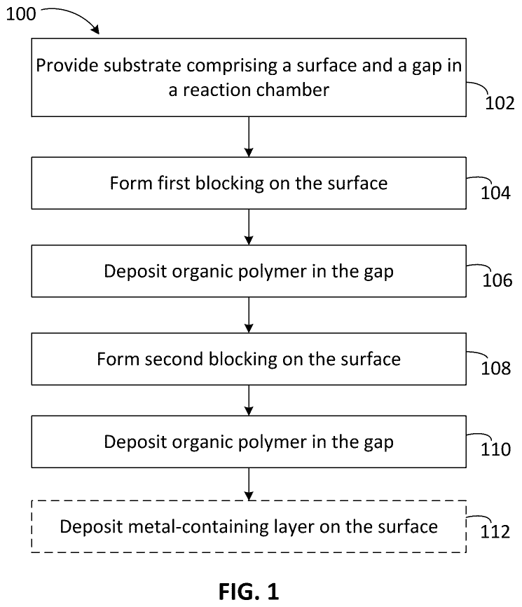

FIG. 1 is a block diagram of exemplary embodiments of a method 100 according to the current disclosure. In the embodiments, an organic polymer is selectively deposited in a gap present on a substrate 106, 110, optionally followed by a selective deposition of a metal-containing layer on the top surface 112. A patterned layer, such as an initial mask is present on the substrate top surface. The initial mask may comprise one or more material layers that function to guide subsequent etching processes to predetermined areas of the substrate located below the hard mask. The substrate typically comprises several material layers below the patterned layer. These layers will contribute to the functioning of a semiconductor device and need to be accurately etched for proper device function. The patterned layer has been prepared by forming gaps, which may be of variable shape, into the patterned material by methods known in the art.

The method 100 of selectively depositing an organic polymer is initiated by the first phase 102 depicted in FIG. 1, as a substrate comprising a gap is provided into a reaction chamber. A substrate according to the current disclosure may comprise, for example, an oxide, such as silicon oxide (for example thermal silicon oxide or native silicon oxide), aluminum oxide, or a transition metal oxide, such as hafnium oxide. In some embodiments, as substrate comprises, consist essentially of, or consist of amorphous carbon, spin-on carbon, spin-on glass, amorphous silicon, or silicon carbide. A substrate may comprise, consist essentially of, or consist of a nitride, such as silicon nitride or titanium nitride, a metal, such as copper, cobalt, tungsten, molybdenum, or ruthenium, chalcogenide material, such as molybdenum sulfide.

The reaction chamber can form part of an atomic layer deposition (ALD) assembly. The reaction chamber can form part of a chemical vapor deposition (CVD) assembly. The assembly may be a single wafer reactor. Alternatively, the assembly may be a batch reactor. The assembly may comprise one or more multi-station deposition chambers. Various phases of method 100 can be performed within a single reaction chamber or they can be performed in multiple reaction chambers, such as reaction chambers of a cluster tool. In some embodiments, the method 100 is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The organic polymer and/or the metal-containing layer according to the current disclosure may be deposited in a cross-flow reaction chamber. The organic polymer and/or the metal-containing layer according to the current disclosure may be deposited in a cross-flow reaction chamber.

The substrate according to the current disclosure comprises a gap. The gap has an inner surface comprising a first material and the top surface comprises a second material. In some embodiments, the gap has a bottom and a side wall. The bottom of the gap may have substantially the same chemical composition as the side wall. In some embodiments, however, the gap has a bottom, and the bottom has a different chemical composition that the side wall. In some embodiments, the composition of the side wall can be different in different parts of the gap. For example, the gap may have been etched though more than one material layer, leading to different materials along the depth of the gap. In some embodiments, the side wall of a gap comprises a titanium nitride layer, a silicon oxide layer, a ruthenium layer, a molybdenum layer, a tungsten layer, a silicon nitride, and/or a low k layer, for example.

In some embodiments, the first material is an electrically conductive material. In some embodiments, the first material is selected from a group consisting of an elemental metal, amorphous carbon, metal oxide and metal nitride. In some embodiments, the first material is a transition metal. In some embodiments, the first material is a metal selected from a group consisting of Ti, Zr, Hf, V, Nb, Ta, Cr, Mo, W, Mn, Fe, Ru, Co, Ni, Cu, Zn and Al. In some embodiments, the first material comprises elemental metal. In some embodiments, the first material consists essentially, or consists of, elemental metal. In some embodiments, the inner surface consists essentially or consists of an elemental metal.

In some embodiments, the first material comprises carbon. In some embodiments, the inner surface consists essentially of, or consists of, carbon, such as amorphous carbon. In some embodiments, the inner surface comprises at least two, or at least three different materials. The variety of different materials depends on the structure of the device in question.

In some embodiments, the second material of the top surface is a dielectric material. In some embodiments, the second material comprises silicon. In some embodiments, the second material is a low-k material. In some embodiments, the second material comprises an oxide. In some embodiments, the second material comprises a nitride. Examples of silicon-comprising dielectric materials include silicon oxide-based materials, including grown or deposited silicon dioxide, doped and/or porous oxides and native oxide on silicon. In some embodiments, the second material comprises silicon oxide. In some embodiments, the second material is a silicon oxide material, such as a native oxide material, a thermal oxide material or a chemical oxide material. In some embodiments, the second material comprises SiN. In some embodiments, the second material comprises carbon. In some embodiments, the second material comprises SiOC.

In some embodiments, the second material may be a SiO₂-based material. In some embodiments, the second material may comprise Si—O bonds. In some embodiments, the second material may comprise a SiO₂-based low-k material. In some embodiments, the second material may comprise more than about 30%, or more than about 50% of SiO₂. In certain embodiments the second material may comprise a silicon dioxide.

In some embodiments, the second material is selected from a group consisting of SiO₂, SiN, SiC, SiOC, SION, SiOCN, SiGe and combinations thereof. The thickness of the material forming the top surface may vary. In some embodiments, the thickness of the material forming the top surface is from 1 nm to about 15 nm, such as about 5 nm or about 10 nm. In some embodiments, the thickness of the material forming the top surface is below about 15 nm, such as below about 10 nm or below about 5 nm. In some embodiments, the top surface comprising the second material is a dielectric material. In some embodiments, the dielectric material is selected from silicon-containing dielectric materials and metal-containing dielectric materials. In some embodiments, the dielectric material comprises a metal oxide or a metal nitride. In some embodiments, the dielectric material is selected from aluminum oxide, hafnium oxide, zirconium oxide, aluminum nitride, tantalum nitride and combinations thereof. In some embodiments, the top surface consists essentially of, or consists of, second material.

The method according to the current disclosure further comprises forming a first blocking on the top surface 104, and selectively depositing an organic polymer from a vapor phase on the inner surface relative to the first blocking 106. In some embodiments, the first blocking comprises treating the top surface with a silylation agent, and thereafter depositing an organic polymer on the inner surface of the gap. In other words, the organic polymer is deposited selectively against a silylated top surface of the substrate at block 106. A silylating agent according to the current disclosure is provided in a vapor phase. In some embodiments, the top surface is silylated by exposure to a silylation agent, such as an alkylsilane, for example allyltrimethylsilane (TMS-A), bis(dimethylamino)dimethylsilane, bis(dimethylamino)diethylsilane, halosilane, for example chlorotrimethylsilane (TMS-Cl) or octadecyltrichlorosilane (ODTCS), an imidazole, for example N-(trimethylsilyl)imidazole (TMS-Im), a silazane, for example hexamethyldisilazane (HMDS), a silylamine, for example N-(trimethylsilyl) dimethylamine or 1,1,1-trimethoxy-N,N-dimethylsilanamine or a pyrrole, such as 1-(triisopropylsilyl)pyrrole. The substrate may be contacted with a sufficient quantity of the blocking agent and for a sufficient period of time that the top surface is selectively blocked with silicon species. In some embodiments, the second material is not passivated with a self-assembled monolayer.

The silylation of the second material may be performed at an elevated temperature. In some embodiments, the silylation is performed at an ambient temperature. In some embodiments, the silylation is performed at a temperature of below about 100° C. In some embodiments, the silylation is performed at a temperature of below about 200° C. In some embodiments, the silylation is performed at a temperature of below about 500° C. In some embodiments, the silylation is performed at a temperature of between about 20° C. and about 200° C.

After the top surface has been blocked, an organic polymer is deposited on the first surface. The first surface may comprise, consists essentially or consist of a conductive material. In some embodiments, the organic polymer consists essentially of, or consists of, polyimide. In some embodiments, the organic polymer is deposited by a cyclic deposition process. In some embodiments, the organic polymer is deposited to substantially fill the gap.

In some embodiments, the organic polymer is deposited by a cyclic process. For example, the deposition of the organic polymer may be an MLD process. In some embodiments, the cyclic deposition process for depositing the organic polymer comprises providing a first organic polymer precursor and a second organic polymer precursor alternately and sequentially into the reaction chamber.

The deposition of an organic polymer comprises providing a first vapor-phase organic polymer precursor into the reaction chamber and providing a second vapor-phase organic polymer precursor into the reaction chamber. Providing a first vapor-phase organic polymer precursor and providing a second vapor-phase organic polymer precursor may define a deposition cycle. The deposition cycle may be repeated until a suitable amount of the organic polymer has been deposited in the gap. The first and second vapor-phase organic polymer precursors form the organic polymer selectively on the first surface. In some embodiments, the organic polymer comprises polyimide. In some embodiments, the organic polymer comprises polyamide.

Various reactants can be used to deposit organic polymer according to the processes described herein. For example, in some embodiments, the first organic polymer precursor is a diamine. In some embodiments, the first reactant can be, for example, 1,6-diaminohexane, 1,3-diaminopentane, triamine, such as tris(2-aminoethyl)amine, or a cyclic compound comprising at least two primary amine groups, such as 1,4-diaminocyclohexane or p-phenylenediamine. In some embodiments, the substrate is contacted with the first organic polymer precursor before it is contacted with the second organic polymer precursor. Thus, in some embodiments, the substrate may be contacted with a diamine before it is contacted with a second organic polymer precursor. However, in some embodiments, the deposition

In some embodiments, the second organic polymer precursor is capable of reacting with adsorbed species of the first reactant under the deposition conditions. For example, in some embodiments, the second organic polymer precursor is an anhydride, such as furan-2,5-dione (maleic acid anhydride). The anhydride can be a dianhydride, e.g., pyromellitic dianhydride (PMDA). In some embodiments, the second reactant can be any other monomer with two reactive groups which will react with the first reactant.

In some embodiments, the organic polymer precursors do not contain metal atoms. In some embodiments, the organic polymer precursors do not contain semimetal atoms. In some embodiments, one of the organic polymer precursors comprises metal or semimetal atoms. In some embodiments, the organic polymer precursors contain carbon and hydrogen and one or more of the following elements: N, O, S, P or a halide, such as Cl or F.

In some embodiments, organic polymer precursors for use in the selective deposition of an organic polymer may be aliphatic compounds comprising 1-6 carbon atoms, 2-5 carbon atoms, 2-4 carbon atoms, 5 or fewer carbon atoms, 4 or fewer carbon atoms, 3 or fewer carbon atoms, or 2 carbon atoms. In some embodiments, the bonds between carbon atoms in the reactant or precursor may be single bonds, double bonds, triple bonds, or some combination thereof. Thus, in some embodiments, a first organic polymer precursor may comprise two amino groups. In some embodiments, the amino groups of a first organic polymer precursor may occupy one or both terminal positions on an aliphatic carbon chain. However, in some embodiments, the amino groups of a first organic polymer precursor may not occupy either terminal position on an aliphatic carbon chain. In some embodiments, a first organic polymer precursor may comprise a diamine. In some embodiments, a first organic polymer precursor may comprise an organic polymer precursor selected from the group of 1,2-diaminoethane, 1,3-diaminopropane, 1,4-diaminobutane, 1,5-diaminopentane, 1,2-diaminopropane, 2,3-butanediamine, 2,2-dimethyl-1,3-propanediamine.

In some embodiments, the first organic polymer precursor provided into the reaction chamber at is a liquid precursor under standard conditions. In some embodiments, the first organic polymer precursor being vaporized comprises a diamine, such as 1,6-diaminohexane, 1,3-diaminopentane, triamine, such as tris(2-aminoethyl)amine, or a cyclic compound comprising at least two primary amine groups, such as 1,4-diaminocyclohexane or p-phenylenediamine. The substrate is then exposed to the first organic polymer precursor vapor 210a. The substrate is also exposed to a second vapor-phase precursor 210b, for example an organic polymer precursor, such as a dianhydride. A dianhydride may be, for example, pyromellitic dianhydride (PMDA). The cyclic exposure of the substrate to the first and second organic polymer precursors leads to the deposition of an organic polymer. The method can include additional steps, and may be repeated, but need not be performed in the illustrated sequence nor the same sequence in each repetition, and it can be readily extended to more complex vapor deposition techniques.

The first organic polymer precursor according to the current disclosure may comprise at least two carbon atoms, such as 1,2-diaminoethane. In some embodiments, first organic polymer precursor comprises three carbon atoms. In some embodiments, first organic polymer precursor comprises four carbon atoms. For example, first organic polymer precursor may be selected from 1,2-diaminobutane, 1,3-diaminobutane, 1,4-diaminobutane and 2,4-diaminobutane. Thus, in some embodiments, at least one of the amino groups is attached to a carbon atom that is bonded to two other carbon atoms. In other words, at least one of the amino groups may be located at the end of a carbon chain. In some embodiments, a diamine according to the current comprises five carbon atoms. In some embodiments, a diamine according to the current comprises six carbon atoms.

In some embodiments, the carbon chain of the first organic polymer precursor is branched. Thus, there is at least one carbon atom which is bonded to three or four other carbon atoms. In some embodiments, there is one such branching position in the first organic polymer precursor. In some embodiments, there are two such branching positions in the first organic polymer precursor. In some embodiments, there are three or more branching points. In some embodiments, the side chain from the longer carbon chain is a methyl group. In some embodiments, the side chain from the longer carbon chain is an ethyl group. In some embodiments, the side chain from the longer carbon chain is a propyl group. In some embodiments, the side chain from the longer carbon chain is an isopropyl group. In some embodiments, the side chain from the longer carbon chain is a butyl group. In some embodiments, the side chain from the longer carbon chain is a tert-butyl group. In some embodiments, a side chain of a first organic polymer precursor is a straight alkyl chain. In some embodiments, a side chain of a first organic polymer precursor is a branched alkyl chain. In some embodiments, a side chain of a first organic polymer precursor is a cyclic alkyl chain.

In some embodiments, the first organic polymer precursor is a C2 to C11 compound. The number of carbon atoms in the first organic polymer precursor typically influences the volatility of the compound such that a higher-weight compound may not be as volatile as a smaller compound. However, it was found out that intermediate-sized first organic polymer precursors containing, for example, four, five or six carbon atoms, may have suitable properties for being used as a first organic polymer precursor in the selective deposition processes according to the current disclosure. For example, 1,3-diaminopentane is liquid at room temperature, has a boiling point of 164° C. under atmospheric pressure, a vapor pressure of about 2.22 Torr at 25° C. and reaches a vapor pressure of 1 Torr at temperatures below 20° C. Thus, when 1,3-diaminopentane is used as a precursor for organic polymer deposition according to the current disclosure, the precursor vessel does not need to be heated. This may be advantageous for the on-tool lifetime of the precursor, as it may be less prone to degradation during continued use. Further, a liquid precursor has an advantage that precursor vessel loading is less expensive than for solid precursors. In some embodiments, the first organic polymer precursor comprises 1,3-diaminopentane.

In some embodiments of the disclosure, the amine groups are attached to non-adjacent carbon atoms. This may have advantages for the availability for the amine groups to reactions with the second precursor. In some embodiments, there is one carbon atom between the amino group-binding carbon atoms. In some embodiments, there is at least one carbon atom between the amino group-binding carbon atoms. In some embodiments, there are two carbon atoms between the amino group-binding carbon atoms. In some embodiments, there are at least two carbon atoms between the amino group-binding carbon atoms. In some embodiments, there are three carbon atoms between the amino group-binding carbon atoms. In some embodiments, there are at least three carbon atoms between the amino group-binding carbon atoms. In some embodiments, there are four carbon atoms between the amino group-binding carbon atoms. In some embodiments, there are at least four carbon atoms between the amino group-binding carbon atoms.

In some embodiments, the first organic polymer precursor comprises 1,5-diamino-2-methylpentane. Although the vapor pressure of 1,5-diamino-2-methylpentane is lower than that of 1,3-diaminopentane, it is also liquid at ambient temperature, and reaching vapor pressure of 1 Torr requires a moderate temperature of about 40° C.

In some embodiments, a carbon atom bonded with an amine nitrogen in the first organic polymer precursor is bonded to at least two carbon atoms. Thus, in some embodiments in which the first organic polymer precursor comprises five or more carbons, at least one of the amino groups may be located away from the end of a carbon chain. The structure of the first organic polymer precursor affects its properties in a vapor deposition process. Branching of a first organic polymer precursor, including the number of branches, and the relative position of the amino groups to the branches, may cause the deposited organic polymer to have different properties. Without limiting the current disclosure to any specific theory, for example steric factors, may lead to certain reactions being preferred in This may offer the possibility to design a deposition process for a given purpose, taking into account for example the thermal budget, organic polymer growth speed requirements, necessary degree of selectivity, by using different first organic polymer precursors.

In some embodiments, the first organic polymer precursor is a cyclic diamine. In some embodiments, the first organic polymer precursor comprises a cyclohexanedialkylamine, cyclopentadienedialkylamine, cyclopentanedialkylamine, benzenedialkylamine, cyclopentanetrialkylamine, cyclohexanetrialkylamine, cyclopentadienetrialkylamine and benzenetrialkylamine.

In some embodiments, the first organic polymer precursor is an aromatic diamine. In some embodiments, the aromatic diamine is a diaminobenzene, such as 1,2-diaminobenzene, 1,3-diaminobenzene or 1,4-diaminobenzene. In some embodiments, the aromatic diamine comprises an alkylamino group in at least one position. For example, the alkylamino group may be a C1 to C3 alkylamino group, such as —CH2NH2, —(CH2)2NH2, —(CH2)3NH2, —CH(CH3)NH2 or —CH2CH(CH3)NH2.

In some embodiments, the first organic polymer precursor is selected from a group consisting of 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 2,5-diaminohexane, 1,3-diamino-5-methylhexane, 4,4,4-trifluoro-1,3-diamino-3-methylbutane, 2,4-diamino-2-methylpentane, 4-(1-methylethyl)-1,5-diaminohexane, 3-aminobutanamide, 1,3-diamino-2-ethylhexane, 2,7-diamino-2,7-dimethyloctane, 1,3-diaminobenzene and 1,4-diaminobenzene. In some embodiments, the first organic polymer precursor comprises a halogen.

In some embodiments, triamines may be used in the deposition of organic polymer according to the current invention. Providing such molecules may advantageously affect the availability of polymerization sites for the second vapor-phase organic polymer precursor. The availability of three amine groups in a single molecule, may lead to denser polymer network, which again may reduce the metal migration through the organic polymer. Such properties may be advantageous in embodiments utilizing the organic polymer according to the current disclosure as a passivation layer. Examples of suitable triamines include 1,2,3-triaminopropane, triamino butane (with amines in carbons 1, 2 and 3 or in carbons 1, 2 and 4), triamino pentane (especially with amines in carbons 1 and 5, plus in any one of the carbons 2, 3 or 4). Similarly, triamino hexanes may contain amine groups in carbons 1 and 6, as well as in any one of the positions 2, 3, 4 or 5; triamino heptanes may contain amine groups in carbons 1 and 7, as well as in any one of the positions 2, 3, 4, 5 or 6; and triamino octanes may contain amine groups in carbons 1 and 8, as well as in any one of the positions 2, 3, 4, 5, 6 or 7. Further, branched carbon chains, notably 2-aminomethyl-1,3-diaminopropane, 2-aminomethyl-1,4-diaminobutane (or alternatives having the two amino groups elsewhere in the butane chain), 2-aminomethyl-1,5-diaminopentane (or alternatives having the two amino groups elsewhere in the pentane chain), 3-aminomethyl-1,5-diaminopentane (or alternatives having the two amino groups elsewhere in the pentane chain), 2-aminomethyl-1,6-diaminohexane (or alternatives having the two amino groups elsewhere in the hexane chain), 3-aminomethyl-1,6-diaminohexane (or alternatives having the two amino groups elsewhere in the hexane chain), 3-aminoethyl-1,6-diaminohexane (or alternatives having the two amino groups elsewhere in the hexane chain). Also, an aromatic triamine, such as 1,3,5-triaminobenzene, may be an alternative for certain embodiments.

In some embodiments, the second vapor-phase organic polymer precursor comprises pyromellitic dianhydride (PMDA).

In some embodiments, the polymer deposited comprises polyimide. Thus, in some embodiments, the organic polymer comprises polyimide. In some embodiments, the organic polymer consists substantially only of polyimide. In some embodiments, the organic polymer comprises polyamic acid. In some embodiments, the organic polymer consists substantially only of polyamic acid and polyimide. In some embodiments, the organic polymer is deposited at temperatures below 190° C., and subsequently heat-treated (annealed) at a temperature of about 190° C. or higher (such as from about 200° C. to about 500° C.) to increase the proportion of the organic polymer from polyamic acid to polyimide. Other examples of deposited polymers include dimers, trimers, polyurethanes, polythioureas, polyesters, polyimines, other polymeric forms or mixtures of the above materials.

In some embodiments the substrate is thermally annealed for a period of about 1 to about 15 minutes. In some embodiments the substrate is thermally annealed at a temperature of about 200 to about 500° C. In some embodiments the thermal anneal step comprises two or more steps in which the substrate is thermally annealed for a first period of time at a first temperature and then thermally annealed for a second period of time at a second temperature.

In some embodiments, the deposited organic polymer is exposed to reactive species generated from plasma. This may improve the passivation properties of the organic polymer in embodiments in which it is used as a passivation material. For example, reactive species generated from hydrogen- and argon-comprising plasma can be used. The organic polymer may be exposed to plasma from about 1 seconds to about 1 minute, such as from about 1 second to about 30 seconds, or from about 5 seconds to about 30 seconds, or for about 1 second to about 15 seconds, or from about 3 seconds to about 20 seconds, for example for about 5 seconds, for about 10 seconds, for about 20 seconds or for about 30 seconds. A plasma power of at least about 20 W, or at least about 50 W, such as from about 20 W to about 100 W, such as 30 W, 50 W or 70 W, may be used. The suitable plasma power and duration of the plasma exposure may be determined experimentally.

In some embodiments, alternatively or in addition to the plasma treatment aimed at amending the properties of the organic polymer, a plasma treatment may be used to at least partially remove blocking from the first surface. In such embodiments, higher plasma energy is typically used, which may negatively affect the passivation properties of the organic polymer, for example, through removal of some of the organic polymer The blocking according to the current disclosure may have the advantage of requiring less of removing than alternative inhibitor reactants. This may be beneficial, as the damage to the organic polymer—and possibly to other surfaces exposed to plasma—may be reduced. This may improve the selectivity of the subsequent deposition steps. Further, the inhibitor reactants according to the current disclosure may allow the growth of target material after shorter plasma exposure than conventional inhibitor reactants and inhibitor materials deposited using them.

Additional treatments, such as heat or chemical treatment, can be conducted prior to, after or between the processing steps described herein. For example, treatments may modify the surfaces or remove portions of the material on the substrate surfaces exposed at various stages of the process. In some embodiments, the substrate may be pretreated or cleaned prior to or at the beginning of the selective deposition of organic polymer. In some embodiments, a pretreatment or cleaning process may be carried out in the same reaction chamber as a selective deposition of organic polymer, however in some embodiments a pretreatment or cleaning process may be carried out in a separate reaction chamber. Further, forming of blocking and deposition of an organic polymer may be performed in the same reaction chamber, or in separate reaction chambers of the same cluster tool. Forming the blocking and deposition of an organic polymer may be performed in the same deposition station, or in separate deposition stations of a multi-station chamber.

In some embodiments, the cyclic process comprises providing a first organic polymer precursor and a second organic polymer precursor alternately and sequentially into the reaction chamber. In some embodiments, the organic polymer is deposited to substantially fill the gap. In some embodiments, the organic polymer is deposited until its surface is substantially flush with or higher than the top surface. In some embodiments, the organic polymer is deposited until it grows out of the gap. In some embodiments, the organic polymer is not deposited laterally outside the gap. In some embodiments, the method according to the current disclosure comprises an etch-back phase to adjust the surface of the organic polymer. In some embodiments, trimming of the substrate after depositing organic polymer comprises an etch-back of the organic polymer.

The purpose of depositing organic polymer inside the gap is to avoid the deposition of the metal-containing layer, such as an etch-stop layer in the gap. The organic polymer is a sacrificial material that is not necessarily present in the final structure or device according to the current disclosure. Therefore, the deposition of the organic polymer does not need to be uniform in the gap, and the deposition of the organic polymer does not need to fill the gap completely. Therefore, the organic polymer may form an air gap in the gap. In other words, the gap can be pinched off by the growth of the organic polymer, leaving an empty cavity inside the gap. Without limiting the current disclosure to any specific theory, gravity or other physical conditions may affect the organic polymer also after deposition. Thus, in some embodiments, the organic polymer may collapse, or otherwise deform so that the cavity is not visible, or present. Further, the surface of the organic polymer may be uneven, concave or otherwise uneven. The uniformity and possible presence of an air gap in the gap may vary according to the composition and/or layer structure of the gap. In some embodiments, there are other materials exposed on the inner surface of the gap in addition to the first material. The organic polymer may or may not be deposited on such additional materials. For example, in some embodiments, second material may be present on the inside of the gap. Although the second material forms the top surface, there may be one or more additional layers of the second material either above or below the first material.

In embodiments, in which the inner surface of the gap comprises further materials in addition to the first material, and the organic polymer is not deposited on such materials, the growth of the organic polymer may be uneven. However, the organic polymer is inherently deposited on itself. It will therefore reach the top of the gap even in embodiment in which the inner surface of the gap contains materials on which the organic polymer does not deposit.

In some embodiments, the organic polymer is deposited substantially conformally on inner surfaces of the gap.

In some embodiments, the process according to the current disclosure comprises depositing an organic polymer on the first material to selectively passivate the first material for selectively depositing an etch-stop layer on the second material. The deposition of organic polymer may comprises providing a first polymer precursor, such as acetic anhydride, and a second polymer precursor, such as a diamine or a triamine, alternately and sequentially into the reaction chamber. An organic polymer may be provided by a cyclic deposition process. For example, polyimide-comprising organic polymer may be deposited by providing an acetic anhydride and a diamine alternately and sequentially into a reaction chamber to form an organic polymer on the first surface.

After depositing a predetermined amount of the organic polymer 106, a second blocking is formed on the top surface 108 and an organic polymer is selectively deposited from a vapor phase on the inner surface relative to the second blocking 110.

The effect of the first blocking may be reduced over multiple deposition cycles of the organic polymer, whereby the selectivity of the deposition is lost. At that stage, organic polymer may begin to deposit on the top surface. The inventors surprisingly found out that the blocking cannot be directly repeated, but additional steps are needed to keep selectively depositing the organic polymer in the gap. Without limiting the current disclosure to any specific theory, forming the second blocking may be performed by recovering hydroxyl groups on the blocked surface of the substrate. In some embodiments, performing the second blocking comprises removing the first blocking. The first blocking may be removed by a plasma treatment. The first blocking may be removed by an oxidation treatment. In some embodiments, forming the second blocking comprises re-activating the first blocking. The first blocking may be activated by an air-break, i.e. exposing the substrate to ambient conditions. In some embodiments, the duration of the air break is from about 10 seconds to about 10 minutes, such as about 20 seconds, about 30 seconds, about 40 seconds, about 60 seconds, about 1.5 minutes or about 2 minutes or about 5 minutes. However, in embodiments, in which the substrate is exposed to a more controlled atmosphere, the temperature of the substrate may be more carefully controlled. In such embodiments, the substrate is exposed to a gas comprising oxygen and water, and an elevated temperature may be used. For example, the substrate may be exposed to a gas comprising oxygen and water at a temperature from about 20° C. to about 250° C., or from about 50° C. to about 250° C., or from about 50° C. to about 200° C. such as at a temperature of about 30° C. or of about 50° C., or about 100° C., or about 150° C. or about 200° C.

In some embodiments, the first blocking and the second blocking comprise silylating the top surface. In some embodiments, the forming of second blocking is repeated. In some embodiments, the deposition of an organic polymer is continued after forming the second blocking, and after a predetermined amount of deposition, the forming of the second blocking is repeated. The amount of deposition on the organic polymer may be the same or different after forming the second blocking as after forming the first blocking.

In some embodiments, forming the second blocking on the top surface comprises exposing the substrate to a gas mixture comprising oxygen. In some embodiments, forming the second blocking is performed at a temperature of below 100° C.

In some embodiments, the second blocking is formed at a temperature of below about 70° C., or at a temperature of below about 50° C., or at a temperature of below about 40° C., or at a temperature of below about 30° C., or at a temperature of below about 25° C.

In some embodiments, the second blocking is formed at a temperature from about 15° C. to about 150° C., or at a temperature from about 15° C. to about 100° C., or at a temperature from about 15° C. to about 70° C., or at a temperature from about 15° C. to about 50° C., or at a temperature from about 15° C. to about 30° C., or at a temperature from about 15° C. to about 25° C. In some embodiments, forming the second blocking is performed at a temperature of about 10° C., or at a temperature of about 20° C., or at a temperature of about 25° C., or at a temperature of about 30° C., or at a temperature of about 35° C., or at a temperature of about 40° C., or at a temperature of about 50° C., or at a temperature of about 60° C., or at a temperature of about 80° C.

In some embodiments, forming the second blocking comprises removing the first blocking. In some embodiments, the first blocking is removed by a plasma treatment.

After the second blocking, the deposition of organic polymer on the first surface is continued 110 until sufficient filling of the gap has been achieved.

The substrate may be trimmed after depositing the organic polymer has been completed. Trimming may comprise etching back the organic polymer to remove any non-selectively deposited material, removing optional blocking from the top surface, or other treatment. In some embodiments, blocking is removed from the substrate before depositing metal-containing layer. In some embodiments, blocking is removed by a plasma treatment. In some embodiments, the plasma may comprise oxygen atoms, oxygen radicals, oxygen plasma, or combinations thereof. In some embodiments, the plasma treatment may be performed by hydrogen-comprising plasma. In some embodiments, the plasma may comprise hydrogen atoms, hydrogen radicals, hydrogen plasma, or combinations thereof. In some embodiments, the plasma may comprise noble gas species, for example Ar or He species. In some embodiments, the plasma may consist essentially of noble gas species. In some embodiments, the plasma may comprise other species, for example nitrogen atoms, nitrogen radicals, nitrogen plasma, or combinations thereof. In some embodiments, the trimming may comprise exposing the substrate to an etchant comprising oxygen, for example 03. In some embodiments, the substrate may be exposed to an etchant at a temperature of between about 30° C. and about 450° C., or between about 100° C. and about 400° C. In some embodiments, the etchant may be supplied in one continuous pulse or may be supplied in multiple pulses.

In some embodiments, trimming comprises annealing the organic polymer. In some embodiments, annealing may be carried out after etching back. Annealing may be carried out in the same reaction chamber as the deposition of the organic polymer, the same reaction chamber as the etch-back process, or may be carried out in a separate reaction chamber from one or more of those aspects of the process. In some embodiments annealing is carried out in a reaction chamber that is part of a cluster tool and the substrate is moved to one or more different reaction chambers of the cluster tool for additional processing after annealing.

In some embodiments the substrate is annealed for a period of about 1 to about 15 minutes. In some embodiments the substrate is annealed at a temperature of about 200 to about 500° C. In some embodiments the anneal step comprises two or more steps in which the substrate is annealed for a first period of time at a first temperature and then annealed for a second period of time at a second temperature. Both trimming and annealing are optional, and only one of them or both can be performed.

In another aspect, a method of selectively depositing a metal-containing layer on a top surface of a substrate is disclosed. This aspect is indicated in block 112 of FIG. 1. The metal-containing layer is selectively deposited on the top surface relative to the organic polymer. In some embodiments, the metal of the metal containing layer is selected from titanium, aluminum, yttrium, zirconium, hafnium or combinations thereof. In some embodiments, the metal-containing layer is a metal oxide layer. In some embodiments, the metal-containing layer is a metal nitride layer. In some embodiments, the metal-containing layer is a titanium oxide layer. In some embodiments, the metal-containing layer is an yttrium oxide layer. In some embodiments, the metal-containing layer is an aluminum oxide layer. In some embodiments, the metal-containing layer is a hafnium oxide layer. In some embodiments, the metal-containing layer is a zirconium oxide layer. In some embodiments, the metal-containing layer is an aluminum nitride layer.

In some embodiments, the metal-containing layer is deposited by a cyclic deposition process. In some embodiments, the metal-containing layer is deposited by providing a metal precursor and a second precursor in the reaction chamber alternately and sequentially. In some embodiments, the metal-containing layer is deposited by an ALD process. In some embodiments, the metal-containing layer is deposited by a cyclic CVD process. In some embodiments, the metal-containing layer is deposited by a hybrid process.

At phase 112, a metal-containing layer, such as an etch-stop layer, is selectively deposited on the second material. At this stage, the top surface of the substrate comprises the second material on the top surface, and the organic polymer material in the gap, and the metal-containing layer is selectively deposited on the second material relative to the organic polymer material.

In some embodiments, the metal-containing layer is an etch-stop layer comprising a metal oxide. In some embodiments, the etch-stop layer comprises a metal oxide comprising two metals. In some embodiments, the etch-stop layer comprises a metal oxide comprising three metals. In some embodiments, the metal of the etch-stop layer is selected from titanium, aluminum, yttrium, zirconium or combinations thereof. In some embodiments, the etch-stop layer comprises, consists essentially of, or consists of titanium oxide. In some embodiments, the etch-stop layer comprises, consists essentially of, or consists of aluminum oxide. In some embodiments, aluminum oxide is doped with another metal. In some embodiments, the etch-stop layer comprises, consists essentially of, or consists of yttrium oxide. In some embodiments, yttrium oxide is doped with another metal. In some embodiments, the etch-stop layer comprises, consists essentially of, or consists of zirconium oxide. In some embodiments, the etch-stop layer comprises, consists essentially of, or consists of aluminum-doped yttrium oxide. In some embodiments, the etch-stop layer comprises, consists essentially of, or consists of yttrium-doped aluminum oxide. In some embodiments, the etch-stop layer comprises, consists essentially of, or consists of zirconium-doped aluminum oxide. In some embodiments, the etch-stop layer comprises, consists essentially of, or consists of zirconium-doped yttrium oxide. In some embodiments, the etch-stop layer comprises, consists essentially of, or consists of yttrium silicon oxide. In some embodiments, the etch-stop layer comprises a nitride. In some embodiments, the nitride is titanium nitride or titanium oxynitride.

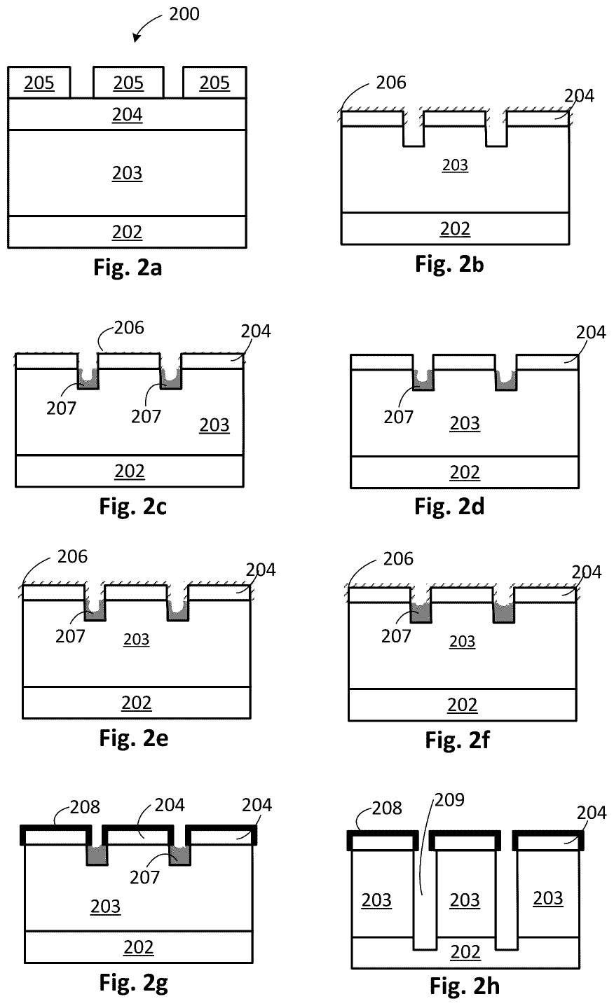

FIGS. 2a-2h depicts the method according to the current disclosure in a schematic form. The figure indicates a semiconductor substrate with a partially fabricated device 200. The silicon substrate 202 is depicted as the bottom-most layer. An amorphous carbon layer 203 is positioned on the silicon substrate 202. Although only the amorphous carbon layer 203 is depicted in the figure for simplicity, the actual structure on which the method according to the current disclosure is performed, may contain multiple layers of different composition and thickness. In exemplary embodiments, layer 203 may comprise, for example one or more of the following: titanium nitride, tantalum nitride, metals such as ruthenium or tungsten, metal oxides such as hafnium oxide, zirconium oxide, lanthanum oxide, scandium oxide, yttrium oxide or aluminum oxide, silicon dioxide, various low k materials, such as SiOC or silicon.

In FIGS. 2a-2h, the thickness of the amorphous carbon layer 203 is approximately 35 nm, but an etching process according to the current disclosure can be performed on thicker or thinner material layers as well. In some embodiments, etching is performed to form a gap having a depth of at least 20 nm. In some embodiments, etching is performed to form a gap having a depth of at least 30 nm. In some embodiments, etching is performed to form a gap having a depth of at least 50 nm. In some embodiments, etching is performed to form a gap having a depth of at least 80 nm. In some embodiments, etching is performed to form a gap having a depth of at least 100 nm. In some embodiments, etching is performed to form a gap having a depth of at least 150 nm.

FIG. 2a indicates a substrate 200 comprising a patterned layer 205 before the deposition of an organic polymer. The patterned layer may be, for example, a photoresist and it is used to guide the formation of a gap to the desired areas of the device 200.

FIG. 2b depicts the substrate of FIG. 2a after the pattern transfer from the photoresist on the substrate. The pattern has been transferred through an initial mask layer 204 to the amorphous carbon layer 203. The initial mask 204 comprises a second material, and also forms the top surface according to the current disclosure. The portion of the gap extending into the amorphous carbon (or other material) layer 203 comprises the inner surface comprising the first material. Thus, the first material may be any of the materials through which the etched gap extends. In some embodiments, there may be more than one first material. However, for the purposes of the current disclosure, the organic polymer does not need to be deposited on all of the materials present in the inner surface of the gap. The organic polymer may grow on itself, enabling sufficient filling of the gap even if its growth is not uniform throughout the gap. After the organic polymer has been deposited into the gap, the gap may continue to have cavities in it. If the growth of the organic polymer has pinched off the gap—which may happen especially for gaps having small critical dimensions, such as critical dimensions under 20 nm, under 15 nm, or under 10 nm—the organic polymer may sufficiently fill the gap for the purposes of the current disclosure. Further, as the organic polymer is a sacrificial material, and its purpose is to prevent the growth of the metal-containing material in later stages of the process, the requirements for its uniformity or quality

FIG. 2b, the photoresist has been removed, and the thickness of the initial mask 204 has been reduced in the process. FIG. 2b thus exemplifies a situation in which the current method may be advantageous: The etching may of the pattern may need to reach so deep into the device structure that the initial mask 204 is not sufficiently etch resistant to accommodate the whole depth of the necessary etching. Thus, the deeper the gap formed by etching is, the more risk there is to alter the critical dimension of the gap opening.

FIG. 2b further indicates a blocking 206 on the initial mask 204, illustrated by hatching. In the embodiment of FIGS. 2a-2h, the initial mask is a silicon-containing material, such as SiOC, i.e. the second material comprises silicon. The blocking according to the current disclosure may be performed by a selective silylation, in which the silicon-comprising material of the initial mask 204 is modified. Exemplary silylation agent may be, for example an alkylsilane, for example a silylamine, for example N-(trimethylsilyl)dimethylamine or 1,1,1-trimethoxy-N,N-dimethylsilanamine. The blocking may be performed at a temperature of from about 100° C. to about 350° C., such as from about 150° C. to about 300° C., such as at a temperature of about 200° C., or about 225° C., or about 250° C.

The thickness of the initial mask 204 may be, for example from about 3 nm to about 20 nm. In some embodiments, the thickness of the initial mask 204 is from about 5 nm to about 20 nm, or from about 5 nm to about 15 nm, or from about 5 nm to about 10 nm. The silylation may be formed throughout the initial mask (i.e. covering all the surfaces comprising the second material). In the figure, as the top surface (i.e. the initial mask comprising silicon) 204 has an observable thickness, silylation covers also the gap-facing surface of the initial mask 204. However, there is no definite minimum thickness for the second material-comprising top surface 204, as for the purposes of the current disclosure, it is sufficient that the top surface (i.e. the top-most horizontal area of the layer) can be blocked.

FIG. 2c indicates the next phase in the process, in which an organic polymer, such as polyimide-comprising material 207, has been selectively deposited on the first surface inside the gap. It can be seen in the figure that the organic polymer 207 does not deposit on the blocked area of the initial mask 204. During the deposition of the organic polymer, the blocking 206 on the top surface 204 may wear out. Without limiting the current disclosure to any specific theory, the top surface terminations on areas covered with the blocking may change, or the blocking terminations may be removed from the top surface. After a predetermined number of deposition cycles of the organic polymer, the level of selectivity may decrease below acceptable limits, or the selectivity may be lost. If the deposition of the organic polymer 207 has not been completed, a second blocking needs to be performed.

However, the inventors of the current disclosure surprisingly discovered that repeating the original blocking does not result in sufficiently selective deposition of the organic polymer. Therefore, in some embodiments, the first blocking may be removed as a part of performing a second blocking. In some embodiments, hydroxyl terminations on the top surface (i.e. in the areas containing a second material) may be created. In some embodiments, second blocking comprises exposing the substrate to ambient conditions. In some embodiments, second blocking comprises exposing the substrate to oxygen. In some embodiments, second blocking comprises exposing the substrate to water vapor. In some embodiments, second blocking comprises exposing the substrate to a gas comprising oxygen and water vapor. In some embodiments, exposing the substrate to ambient conditions has a duration of at least about 5 minutes, or at least about 10 minutes. In some embodiments, exposing the substrate to ambient conditions has a duration of at most about 5 minutes, or at most about 10 minutes. In some embodiments, exposing the substrate to ambient conditions has a duration of between about 5 minutes and about 10 minutes. In some embodiments, exposing the substrate to a gas comprising oxygen and water vapor has a duration of at least 5 minutes, or at least 10 minutes. In some embodiments, exposing the substrate to a gas comprising oxygen and water vapor has a duration of at most about 5 minutes, or at most about 10 minutes. In some embodiments, exposing the substrate to a gas comprising oxygen and water vapor has a duration of between about 5 minutes and about 10 minutes.

In some embodiments, exposing the substrate to a gas comprising oxygen and water vapor is performed at a temperature from about 15° C. to about 150° C. In some embodiments, exposing the substrate to a gas comprising oxygen and water vapor is performed at a temperature from about 15° C. to about 100° C. In some embodiments, exposing the substrate to a gas comprising oxygen and water vapor is performed at a temperature from about 15° C. to about 50° C. In some embodiments, exposing the substrate to a gas comprising oxygen and water vapor is performed at a temperature from about 15° C. to about 30° C. Ambient conditions for the purposes of the current disclosure mean a temperature of about 20° C., exposure to ambient air and normal pressure.

FIG. 2d indicates an optional phase, in which the first blocking has been removed from the top surface 204 of the substrate. This may be an intermediate phase before forming the second blocking on the top surface 204. Organic polymer 207 is still present on the inner surface of the gap, in the embodiment of FIGS. 2a-2h, on the bottom and side walls of the gap. However, depending on the presence of different materials on the inner surface, the organic polymer may be deposited to various areas of the gap. For, example, if the first material, such as amorphous carbon, is present only at the bottom of the gap, the organic polymer growth is initiated from the bottom, and it grows towards the top of the gap by growing on itself. On the other hand, in some embodiments, the first material may be present on the side wall of the gap, and in such embodiments, that is the growth initiation area of the organic polymer. The first material may be present on the majority of the inner surface of the gap, or only in certain areas of it, such as in the form of a layer within the substrate.

FIG. 2e, the top surface 204 of the substrate comprises a second blocking 206. As visible in the figure, the second blocking 206 is present on all areas comprising the second material 204.

FIG. 2f, the deposition of the organic polymer 207 has been continued to the level of the second blocking 206. Although not depicted in FIG. 2f, the deposition of the organic polymer 207 could continue until the level of the top surface 204, since the organic polymer may grow on itself without depositing on the blocked area of the inner surface of the gap. In some embodiments, the organic polymer may even be overgrown from the gap, and trimmed to a desired level.

FIG. 2g depicts the deposited metal-containing layer 208. In some embodiments, the blocking 206 is removed before depositing the metal-containing material. In some embodiments, the metal-containing material is deposited on the top surface 204 without removing the blocking 206. The metal-containing material may serve as an etch-stop layer as in FIG. 2h and protect the areas between the gaps from etching. In some embodiments, the etching is performed to form a gate cut in a gate cut last-process. In some embodiments, the etching may create a gap having a depth of at least about 100 nm, or at least about 150 nm, or at least about 200 nm. In some embodiments, the diameter of the gap being formed is less than about 40 nm, or less than about 30 nm, or less than about 25 nm, or less than about 20 nm, or less than about 15 nm. In some embodiments, the etching extends through the whole device structure to the silicon substrate 202.

To summarize the aspects of forming a second blocking on the top surface of the substrate, the first blocking may be removed, for example by a plasma treatment and the surface of the underlying initial mask may be recovered by an exposure to a gas comprising oxygen and/or water vapor. The top surface of the initial mask will then be blocked by, for example, silylation.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of selectively depositing an organic polymer in a gap, the method comprising:
providing a substrate having a top surface and a gap therein in a reaction chamber;
wherein the gap has an inner surface comprising a first material and the top surface comprises a second material;
forming a first blocking on the top surface;
selectively depositing an organic polymer from a vapor phase on the inner surface relative to the first blocking;
after depositing a predetermined amount of the organic polymer, forming a second blocking on the top surface; and
selectively depositing an organic polymer from a vapor phase on the inner surface relative to the second blocking.

2. The method of claim 1, wherein forming the second blocking comprises removing the first blocking.

3. The method of claim 2, wherein the first blocking is removed by a plasma treatment.

4. The method of claim 1, wherein forming the second blocking comprises restoring top surface properties for blocking.

5. The method of claim 1, wherein forming the second blocking on the top surface comprises exposing the substrate to a gas mixture comprising oxygen and water vapor.

6. The method of claim 1, wherein forming the second blocking comprises exposing the substrate to ambient environment.

7. The method of claim 1, wherein forming the second blocking is performed at a temperature of below 100° C.

8. The method of claim 1, wherein the second material comprises silicon.

9. The method of claim 8, wherein the second material is selected from a group consisting of SiO₂, SiN, SiC, SiOC, SION, SiOCN, Si and combinations thereof.

10. The method of claim 1, wherein the first material is an electrically conductive material.

11. The method of claim 10, wherein the first material is selected from a group consisting of SiGe, a metal, amorphous carbon, metal oxide and metal nitride.

12. The method of claim 1, wherein the first material is a transition metal.

13. The method of claim 11, wherein the first material is a metal selected from a group consisting of Ti, Zr, Hf, V, Nb, Ta, Cr, Mo, W, Mn, Fe, Ru, Co, Ni, Cu, Zn and Al.

14. The method of claim 11, wherein the first material comprises elemental metal.

15. The method of claim 1, wherein the first blocking and the second blocking comprise silylating the top surface.

16. The method of claim 1, wherein the forming of second blocking is repeated.

17. The method of claim 1, wherein the organic polymer comprises polyimide.

18. The method of claim 1, wherein the organic polymer is deposited to substantially fill the gap.

19. A method of selectively depositing a metal-containing layer on a top surface of a substrate, the method comprising:
providing the substrate having a top surface and a gap therein in a reaction chamber; wherein the gap has an inner surface comprising a first material and the top surface comprises a second material;
forming a first blocking on the top surface;
selectively depositing an organic polymer from a vapor phase on the inner surface relative to the first blocking;
after depositing a predetermined amount of the organic polymer, forming a second blocking on the top surface; and
selectively depositing an organic polymer from a vapor phase on the inner surface relative to the second blocking; and
selectively depositing the metal-containing layer on the top surface relative to the organic polymer.

20. The method of claim 19, wherein the metal-containing layer is a metal oxide layer or a metal nitride layer.

21. The method of claim 20, wherein the metal-containing layer is an aluminum oxide layer or an yttrium oxide layer.

22. The method of claim 19, wherein the metal containing layer is an etch-stop layer.

23. The method of claim 22, wherein the etch-stop layer consists substantially of yttrium oxide.

24. The method of claim 19, wherein the metal-containing layer comprises a high k material.

25. A semiconductor structure formed by a method of claim 1.

26. A deposition assembly for depositing an etch-stop layer on a patterned substrate, wherein the deposition assembly is configured and arranged to perform a method according to claim 1.
